(19) United States
(12) Patent Application Publication
(10) Pub. No.: US 2010/0128447 A1
(43) Pub. Date: May 27, 2010

(54) MEMORY MODULE HAVING VOLTAGE REGULATOR MODULE

(75) Inventors: ALAN ROBERT MACDOUGALL, BEAVERTON, OR (US); STEVEN J. MILLARD, MECHANICSBURG, PA (US); JAMES A. LEIDY, HUMMELSTOWN, PA (US)

Correspondence Address: ROBERT J. KAPALKA;TYCO TECHNOLOGY RESOURCES, 4550 NEW LINDEN HILL ROAD, SUITE 140, WILMINGTON, DE, 19808, US

(73) Assignee: TYCO ELECTRONICS CORPORATION, BERWYN, PA (US)

(21) Appl. No.: 12/275,759

(22) Filed: Nov. 21, 2008

(51) Int. Cl. H05K 1/14; H01R 12/18

(52) U.S. Cl. 361/737; 439/62

(57) ABSTRACT

A memory module includes a circuit board having socket mating contacts at a socket interface and VRM contacts at a VRM interface. Memory devices are coupled to the circuit board. The memory devices are electrically connected to corresponding socket mating contacts and the memory devices are electrically connected to corresponding VRM contacts. A voltage regulator module is coupled to the circuit board at the VRM interface. The voltage regulator module is electrically connected to the VRM contacts.

### BACKGROUND OF THE INVENTION

The subject matter herein relates generally to memory modules, and more particularly, to voltage regulator modules for use with memory modules.

Electronic devices, such as computers, workstations and servers, may use numerous types of electronic modules, such as processor and memory modules (e.g. Dynamic Random Access Memory (DRAM), Synchronous Dynamic Random Access Memory (SDRAM), Double Data Rate (DDR) SDRAM, DDR2 SDRAM, DDR3 SDRAM, DDR4 SDRAM or Extended Data Out Random Access Memory (EDO RAM), and the like). The memory modules are produced in a number of formats such as, for example, Single In-line Memory Module (SIMM), or Dual In-line Memory Modules (DIMM). Typically, the memory modules have a circuit board that is installed in a multi-pin socket connector mounted on a system board or motherboard. Each memory module has a card edge that provides an interface generally between two rows of contacts in the socket connector. The memory modules include memory devices mounted on the circuit board that store data for the electronic device. The memory devices require power to operate, and the power is supplied to the memory devices by the contacts within the socket connector.

Known electronic devices having memory modules are not without disadvantages. For instance, the power requirement to operate the memory devices has increased over time as the electronic devices are designed to operate more quickly and/or as the amount of data being stored by the memory devices is increased. Typically, a voltage regulator module is provided on the system board or motherboard for controlling the amount of power supplied to the memory modules. For example, in a typical configuration, one voltage regulator controls the power supplied to up to eight memory modules. However, current designs have limitations in the amount of power that can be supplied to the memory modules. For example, the voltage drop downstream of the voltage regulator at the socket connector is high. Additionally, the current carrying capacity of the contacts within the socket connector limits the amount of current that can be passed across the interface between the socket connector and the system board. Moreover, typical memory modules are designed to particular specifications, which limit potential solutions to supplying enough power to the memory modules. For example, some memory modules have specifications that limit the size or footprint of the modules where the corresponding socket connectors have a particular size and contact arrangement. The physical boundary constraints of the modules limit the number and size of the contacts that may be provided within the socket connector.

### BRIEF DESCRIPTION OF THE INVENTION

In one embodiment, a memory module is provided that includes a circuit board having socket mating contacts at a socket interface and VRM contacts at a VRM interface. Memory devices are coupled to the circuit board. The memory devices are electrically connected to corresponding socket mating contacts and the memory devices are electrically connected to corresponding VRM contacts. A voltage regulator module is coupled to the circuit board at the VRM interface. The voltage regulator module is electrically connected to the VRM contacts.

Optionally, the voltage regulator module may be supported by the circuit board. The voltage regulator module may be coupled to the VRM interface remote from the socket interface. The circuit board may be coupled to a system board at the socket interface such that the circuit board is oriented at a right angle with respect to the system board. Optionally, the socket interface may be provided at an edge of the circuit board, and the VRM interface may be provided in a different edge of the circuit board. The circuit board may include a finger at an edge thereof, and the VRM contacts may extend along the finger. The voltage regulator module may include a card edge connector that receives the finger of the circuit board to engage the VRM contacts. Optionally, the voltage regulator module may include a VRM circuit board that is substantially coplanar with the circuit board. Alternatively, the VRM circuit board may be substantially parallel to, and non-coplanar with, the circuit board. Optionally, the voltage regulator module may include an input and an output both coupled to the VRM contacts. The VRM contacts may be electrically connected to corresponding socket mating contacts via the circuit board and the memory devices may be electrically connected to corresponding VRM contacts via the circuit board. Optionally, the memory module may also include a socket connector having an opening where the socket interface is received in the opening. The voltage regulator module may be coupled to the circuit board remote from the socket connector.

In another embodiment, a voltage regulator module for a memory module is provided that includes a circuit board having a power circuit for regulating power, and a VRM connector coupled to the circuit board. The VRM connector is configured to mate with the memory module. The VRM connector has power-in contacts and power-out contacts coupled to the power circuit, wherein the power-in contacts are configured to receive a power supply from the memory module, and wherein the power-out contacts are configured to supply power to the memory module.

In a further embodiment, a memory system is provided for an electronic device having a power source. The memory system includes a system board having a socket connector, where the system board relays power from the power source to the socket connector. The memory system also includes a memory module that is coupled to the socket connector. The memory module includes a circuit board having socket mating contacts at a socket interface and VRM contacts at a VRM interface. At least some of the socket mating contacts are electrically connected to the power source via the socket connector, and at least some of the VRM contacts are electrically connected to corresponding socket mating contacts via the circuit board. Memory devices are coupled to the circuit board. The memory devices are electrically connected to corresponding socket mating contacts and the memory devices are electrically connected to corresponding VRM contacts. A voltage regulator module is coupled to the circuit board at the VRM interface. The voltage regulator module is electrically connected to the VRM contacts.

### BRIEF DESCRIPTION OF THE DRAWINGS

FIG. 1 is a schematic illustration of an electronic device that incorporates a memory system formed in accordance with an exemplary embodiment.

FIG. 2 is a perspective view of a portion of the memory system shown in FIG. 1 illustrating a memory module that includes a voltage regulator module.

FIG. 3 is an exploded perspective view of the memory system shown in FIG. 2.

FIG. 4 is a perspective view of a portion of the memory system shown in FIG. 2, with the voltage regulator module mounted to the memory module in an alternative manner.

FIG. 5 is a perspective view of a portion of the memory system shown in FIG. 2, with the voltage regulator module mounted to the memory module in another alternative manner.

FIG. 6 is a perspective view of a portion of the memory system shown in FIG. 2, with the voltage regulator module mounted to the memory module in yet another alternative manner.

FIG. 7 is a perspective view of a portion of the memory system shown in FIG. 2, with a voltage regulator module mounted to the memory module in another alternative manner.

FIG. 8 illustrates heat sinks coupled to the memory module and voltage regulator module shown in FIG. 7.

### DETAILED DESCRIPTION OF THE INVENTION

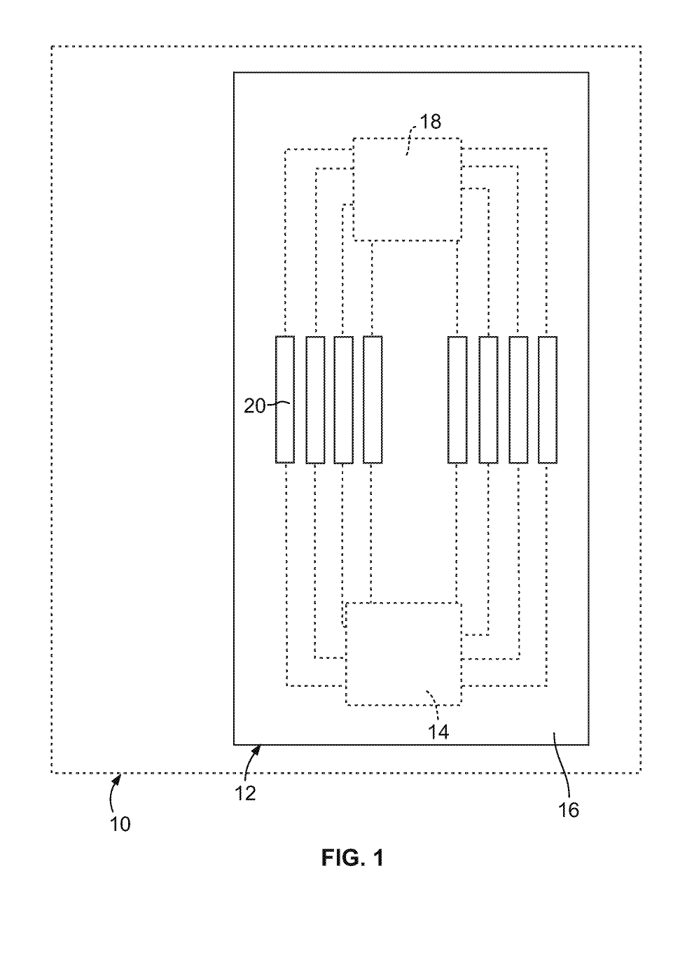

FIG. 1 is a schematic illustration of an electronic device 10 that incorporates a memory system 12 formed in accordance with an exemplary embodiment. The memory system 12 stores data for the electronic device 10. The electronic device 10 a may be any type of electronic device such as, for example, a computer, a workstation, a server, and the like. The electronic device 10 may include one or more electronic modules 14, such as a processor. Optionally, the electronic module 14 may be connected with the memory system 12. For example, the electronic module 14 may be electrically connected to a motherboard or system board 16. The electronic device 10 may also include one or more power sources 18. Optionally, the power source 18 may be connected with the memory system 12. For example, the power source 18 may be electrically connected to the system board 16.

In an exemplary embodiment, the memory system 12 includes one or more memory modules 20 mounted to the system board 16. The memory modules 20 may constitute Synchronous Dynamic Random Access Memory (SDRAM) modules. Optionally, the memory modules 20 may be Dual In-line Memory Modules (DIMM modules). Any number of memory modules 20 may be provided within the memory system 12. Additionally, any number of memory systems 12 may be provided within the electronic device 10.

In an exemplary embodiment, the memory modules 20 are electrically connected to one or more data devices, such as the electronic modules 14, for sending data thereto and/or receiving data therefrom. The memory modules 20 store data generated by the data devices and/or send stored data to the data devices. Optionally, the memory modules 20 may be connected to the data devices via the system board 16. For example, the data devices may be coupled directly to the system board 16, or alternatively, may be provided remote from the system board 16 and connected thereto by an electrical connection. The memory modules 20 are electrically connected to one or more power sources 18 for powering the memory modules 20. The memory modules 20 may be connected to the power source 18 via the system board 16. The power source 18 may be directly coupled to the system board 16, or alternatively, may be provided remote from system board 16 and connected thereto by an electrical connection.

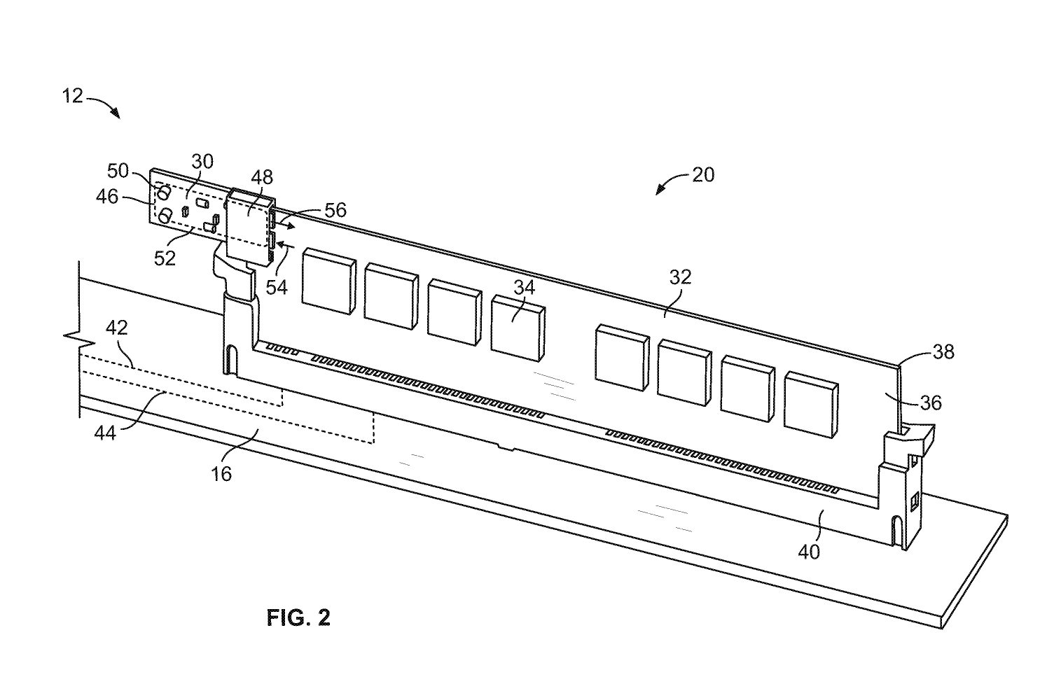

FIG. 2 is a perspective view of a portion of the memory system 12 illustrating one of the memory modules 20 that includes a voltage regulator module 30. The memory module 20 includes a circuit board 32 and a plurality of memory devices 34 coupled to the circuit board 32. The memory devices 34 may be integrated circuit (IC) chips or other electronic components for storing data. Any number of memory devices 34 may be electrically connected to the circuit board 32. In the illustrated embodiment, eight memory devices are mounted to a first side 36 of the circuit board 32. Memory devices 34 may also be mounted to a second side 38 of the circuit board 32.

The memory module 20 is illustrated as being electrically connected to the system board 16. The system board 16 includes a header represented by a socket connector 40 coupled to the system board 16. In the illustrated embodiment, the socket connector 40 constitutes a card edge connector that receives the memory module 20 therein. The socket connector 40 may be configured to orient the circuit board 32 of the memory module 20 at a right angle with respect to the system board 16. Optionally, the system board 16 may have a generally horizontal orientation and the circuit board 32 may have a generally vertical orientation. In an exemplary embodiment, the system board 16 relays both power and data, represented by the arrows 42, 44, respectively, to and/or from the socket connector 40.

The voltage regulator module 30 is electrically connected to the memory module 20. In the illustrated embodiment, the voltage regulator module 30 is coupled to, and supported by, the circuit board 32 of the memory module 20. The voltage regulator module 30 is located remote from the system board 16. The voltage regulator module 30 is electrically coupled to the system board 16 via the circuit board 32 of the memory module 20. The power 42 relayed to the socket connector 40 is routed by the circuit board 32 to the voltage regulator module 30.

The voltage regular module 30 includes a voltage regulator module (VRM) circuit board 46 and a VRM connector 48. The VRM connector 48 may be directly coupled to the memory module 20. In the illustrated embodiment, the VRM connector 48 constitutes a card edge connector that receives a portion of the circuit board 32 to make an electrical connection between the memory module 20 and the voltage regulator module 30. The voltage regular module 30 includes a plurality of components 50, such as resistors, capacitors, traces and/or contacts, that form a power circuit 52. An input 54 and an output 56 are defined by the voltage regular module 30 for the power circuit 52. The input 54 delivers power to the power circuit 52 and the output 56 delivers power from the power circuit 52. Optionally, the components 50 may manipulate the power input 54 coming into the voltage regulator module 30 such that the power output 56 has different power characteristics and the input 54. For example, the power circuit 52 may control and/or regulate a voltage, a current, or another power characteristics of the power output 56.

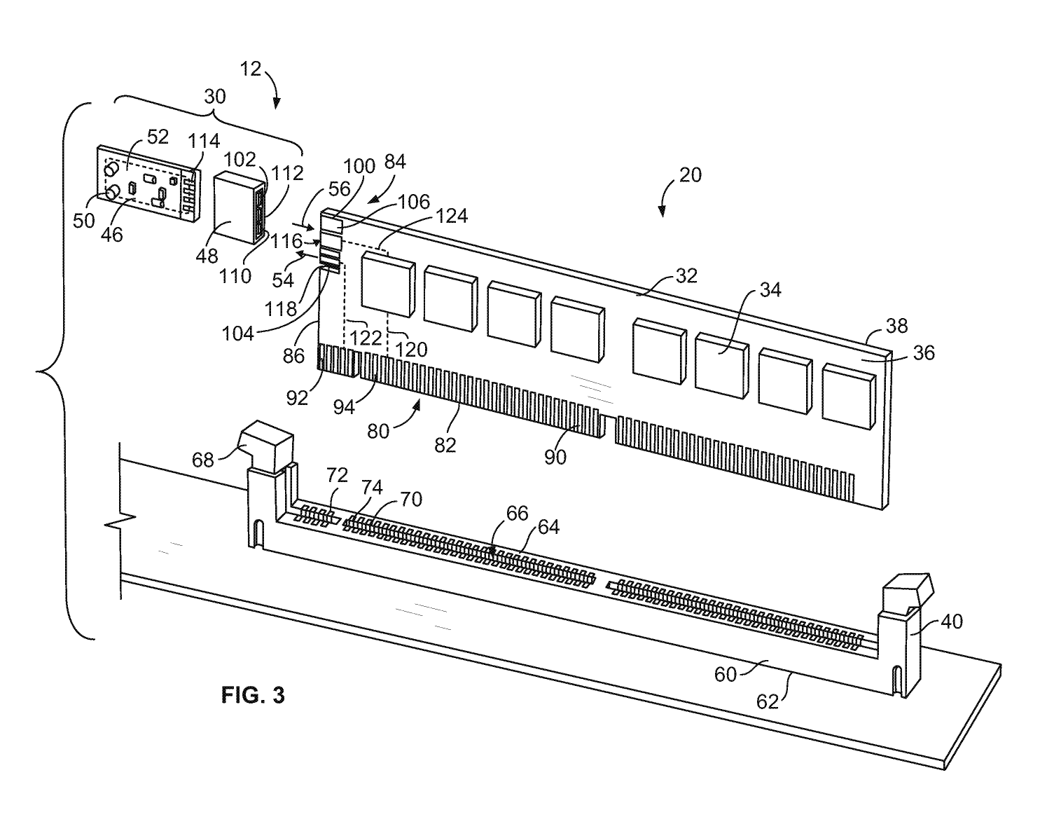

FIG. 3 is an exploded perspective view of the memory system 12. The socket connector 40 includes a housing 60 having a base end 62 mounted to the system board 16. The housing 60 includes a mating end 64 generally opposite the base end 62 for mating with the memory module 20. The housing 60 includes an opening 66 at the mating end 64 for receiving a portion of the circuit board 32 of the memory module 20. For example, the opening 66 may receive a bottom of the circuit board 32 and portions of the sides of the circuit board 32. In an exemplary embodiment, the housing 60 includes latches 68 that hold the memory module 20 within the socket connector 40. The latches extend upward from the mating end 64 away from the system board 16. Optionally, the voltage regulator module 30 may be coupled to the circuit board 32 above the latches 68.

A plurality of socket contacts 70 are held by the housing 60 within the opening 66 for mating with the circuit board 32. The socket contacts 70 may have a predetermined contact pattern for mating with a particular type of memory module 20. Optionally, a subset of the socket contacts 70 may define power contacts 72 and another subset of the socket contacts 70 may define signal or data contacts 74. The socket contacts 70 may define other types of contacts as well, such as ground contacts. In the illustrated embodiment, all of the power contacts 72 are grouped together near one side of the socket connector 40. In alternative embodiments, the power contacts 72 may be positioned elsewhere along the socket connector 16, such as near the center of the socket connector 16, or alternatively the power contacts 72 may be interspersed among the data contacts 74. The power contacts 72 transmit the power 42 routed by the system board 16 to the memory module 20. The data contacts 74 transmit the data 44 between the system board 16 and the memory module 20. Optionally, the power contacts 72 may be substantially identical in size, shape and/or positioning as the data contacts 74, such that the pinout pattern of the system board 16 determines which of the socket contacts 70 receives the power 42, thus defining power contacts 72, and which of the socket contacts 70 receives the data 44, thus defining data contacts 74. As such, the same socket connector 40 may have a different arrangement of power contacts 72 and data contacts 74 depending on the particular system board 16 to which the socket connector 40 is coupled. In an alternative embodiment, rather than the socket contacts 70 being substantially identically formed, the power contacts 72 may be structurally different the data contacts 74. For example, the power contacts 72 may have a different size and shape and/or the power contacts 72 may be made from a different material or have a different coating.

The memory module 20 includes the circuit board 32 with the memory devices 34 and the voltage regulator module 30 coupled thereto. The circuit board 32 includes a socket interface 80 and a first edge 82 and a VRM interface 84 at a second edge 86. The socket interface 80 interfaces with the socket connector 40. The VRM interface 84 interfaces with the voltage regulator module 30. In the illustrated embodiment, the socket interface 80 and the VRM interface 84 both define card edges for mating with card edge connectors. However, in alternative embodiments, separate electrical connectors may be provided at the interfaces 80, 84 for mating with corresponding mating connectors.

A plurality of socket mating contacts 90 are arranged at the socket interface 80 near the first edge 82 of the circuit board 32. The socket mating contacts 90 mate with corresponding socket contacts 70 of the socket connector 40. The socket mating contacts 90 have a similar pattern as the socket contacts 70 for mating thereto. In an exemplary embodiments a subset of the socket mating contacts 90 may define power contacts 92 and another subset of the socket mating contacts 90 may define signal or data contacts 94. The socket mating contacts 90 may define other types of contacts as well, such as ground contacts. The power contacts 92 transmit power from the power contacts 72. The data contacts 94 transmit data between the circuit board 32 and the data contacts 74. Optionally, the power contacts 92 may be substantially identical in size, shape and/or positioning as the data contacts 94, such that the pinout pattern of the socket connectors 40 determines which of the socket mating contacts 90 transmit power, thus defining power contacts 92, and which of the socket mating contacts 90 transmit data, thus defining data contacts 94. In an alternative embodiment, rather than the socket mating contacts 90 being substantially identically formed, the power contacts 92 may be structurally different than the data contacts 94. For example, the power contacts 92 may have a different size and shape and/or the power contacts 92 may be made from a different material or have a different coating.

A plurality of VRM contacts 100 are arranged at the VRM interface 84 near the second edge 86 of the circuit board 32. The VRM contacts 100 are received within the VRM connector 48 of the voltage regulator module 30 to mate with corresponding mating contacts 102 of the VRM connector 48. In an exemplary embodiment, a subset of the VRM contacts 100 may define supply contacts 104 and another subset of the VRM contacts 100 may define receive contacts 106. The VRM contacts 100 may define other types of contacts as well, such as data contacts or ground contacts. The supply contacts 104 transmit power from the memory module 20 to the voltage regulator module 30. The receive contacts 106 transmit power from the voltage regulator module 30 to the memory module 20. The supply contacts 104 define part of the input 54 (shown in FIG. 2) for the voltage regulator module 30, while the receive contacts 106 define part of the output 56 (shown in FIG. 2) for the voltage regulator module 30.

The mating contacts 102 have a subset that defines power-in contacts 110 and another subset that defines power-out contacts 112. The mating contacts 102 may define other types of contacts as well, such as data contacts or ground contacts. The power-in contacts 110 are mated with, and directly engage, the supply contacts 104 and transmit power from the memory module 20 to the voltage regulator module 30. The power-out contacts 112 are mated with, and directly engage, the receive contacts 106 and transmit power from the voltage regulator module 30 to the memory module 20. The power-in contacts 110 define the input 54 (shown in FIG. 2) for the voltage regulator module 30, while the power-out contacts 112 define the output 56 (shown in FIG. 2) for the voltage regulator module 30.

The VRM connector 48 is electrically connected to the VRM circuit board 46. In the illustrated embodiment, the VRM connector 48 is electrically connected to the VRM circuit board 46 such that the mating contacts 102 are electrically connected to board contacts 114 of the VRM circuit board 46. Optionally, the mating contacts 102 are directly terminated to board contacts 114, such as through hole mounting or surface mounting to the VRM circuit board 46. Alternatively, the VRM connector 48 defines a card edge connector interface for receiving an edge of the VRM circuit board 46. In another alternative embodiment, a separate connector extends from the VRM circuit board 46 and is mated with the VRM connector 48. The VRM connector 48 electrically connects the power circuit 52 with the memory module 20.

During assembly, the memory module 20 is coupled to the socket connector 40 by lugging the first edge 82 of the circuit board 32 into the opening 66. The socket mating contacts 90 engage the socket contacts 70 to create an electrical connection therebetween. Power and data can be transmitted between the socket connector 40 and the memory module 20 when the memory module 20 is connected to the socket connector 40. The voltage regulator module 30 is coupled to the memory module 20 by connecting the VRM connector 48 to the circuit board 32. In an exemplary embodiment, the circuit board 32 includes a mounting finger 116 that includes the VRM contacts 100 and is received within the VRM connector 48. The mounting finger 116 is provided at the second edge 86 of the circuit board 32. The mounting finger 116 is located remote from the socket interface 80. Optionally, the mounting finger 116 may be defined by a slot 118 formed in the circuit board 32. The slot 118 receives a portion of the VRM connector 48 during assembly. When assembled, the voltage regulator module 30 is supported by the memory module 20. The voltage regulator module 30 is separate from the system board 16 and is not directly connected to the system board 16.

In operation, power and data is transmitted to the memory module 20 on socket connector 40. The data is transmitted between the data contacts 94 and the memory devices 34 via the circuit board 32, which is represented by the data path 120. Any number of the data contacts 94 may be electrically connected to the memory devices 34 for transmitting data between. The power is transmitted between the power contacts 92 at the socket interface 80 and the supply contacts 104 at the VRM interface 84, which is represented by the power path 122. The power representing the input 54 to the power circuit 52 is supplied by the power path 122. The power circuit 52 regulates and/or controls the power supplied to the memory module 20. The power output from the voltage regulator module 30 to the memory module 20 is supplied to the memory devices 34, which is represented by the power path 124. A power path is thus created between the socket mating contacts 90 and the memory devices 34 via the voltage regulator module 30.

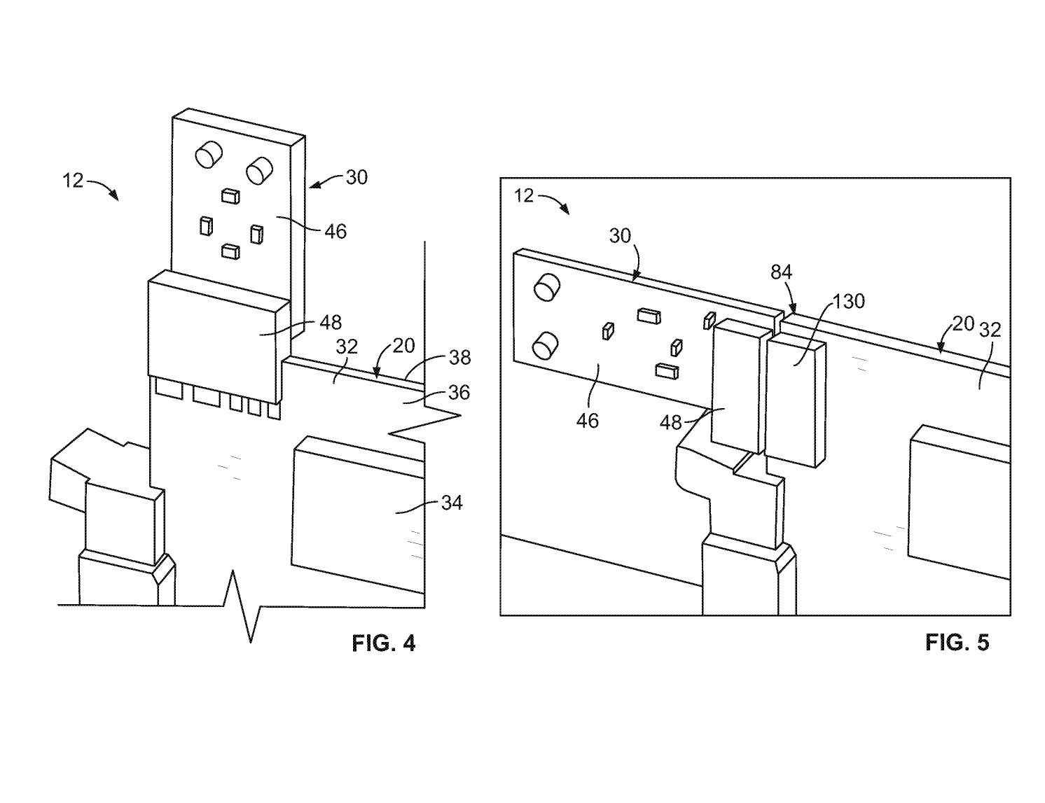

FIG. 4 is a perspective view of a portion of the memory system 12, with the voltage regulator module 30 mounted to the memory module 20 in an alternative manner. The embodiment illustrated in FIG. 4 utilizes similar components as the embodiment illustrated in FIGS. 2 and 3, and like components are identified in FIG. 4 with like reference numerals. The voltage regulator module 30 includes the VRM circuit board 46 with the VRM connector 48 electrically connected to the VRM circuit board 46. The voltage regulator module 30 is connected to the memory module 20 such that the VRM circuit board 46 extends from the circuit board 32 within an outer perimeter defined by the socket connector 40. In one orientation, the circuit board 32 may be oriented generally vertically in the voltage regulator module 30 and extends upward from the circuit board 32. In such a configuration, the overall height of the assembly measured from the system board 16 (shown in FIG. 3) is increased as compared to the embodiment illustrated in FIGS. 2 and 3. However, in such configuration, the overall width of the assembly measured perpendicular to the height, is decreased.

In the illustrated embodiment, the VRM circuit board 46 is oriented generally parallel to the circuit board 32, and the VRM circuit board 46 is non-coplanar with the circuit board 32. For example, the VRM circuit board 46 may be positioned behind the second side 38 of the circuit board 32. An alternative embodiment, the VRM circuit board 46 may be coplanar with the circuit board 32. For example, at least a portion of the VRM circuit board 46 may be aligned with the circuit board 32. When the VRM circuit board 46 is offset, and non-coplanar with the circuit board 32, the overall depth of the assembly, which is measured perpendicular to the height and width, is increased. Optionally, the VRM circuit board 46 is configured to fit within a profile of the memory module 20 as defined between the memory devices 34 on either of the sides 36, 38 of the circuit board 32. As such, a plurality of memory modules 20 may be densely arranged on the system board 16 and the voltage regulator module 30 does not have an impact on the spacing between the memory modules 20.

FIG. 5 is a perspective view of a portion of the memory system 12, with the voltage regulator module 30 mounted to the memory module 20 in another alternative manner. The embodiment illustrated in FIG. 5 utilizes similar components as the embodiment illustrated in FIGS. 2 and 3, and like components are identified in FIG. 5 with like reference numerals. The voltage regulator module 30 includes the VRM circuit board 46 with the VRM connector 48 electrically connected to the VRM circuit board 46. A memory module connector 130 is electrically connected to the circuit board 32 at the VRM interface 84. The VRM connector 48 is mated with the memory module connector 130 to electrically connect the voltage regulator module 30 with the memory module 20. Optionally, one of the connectors 48, 130 defines a plug connector while the other of the connectors 48, 130 defines a receptacle connector. In the illustrated embodiment, when the connectors 48, 130 are mated, the VRM circuit board 46 is parallel to, and coplanar with, the circuit board 32.

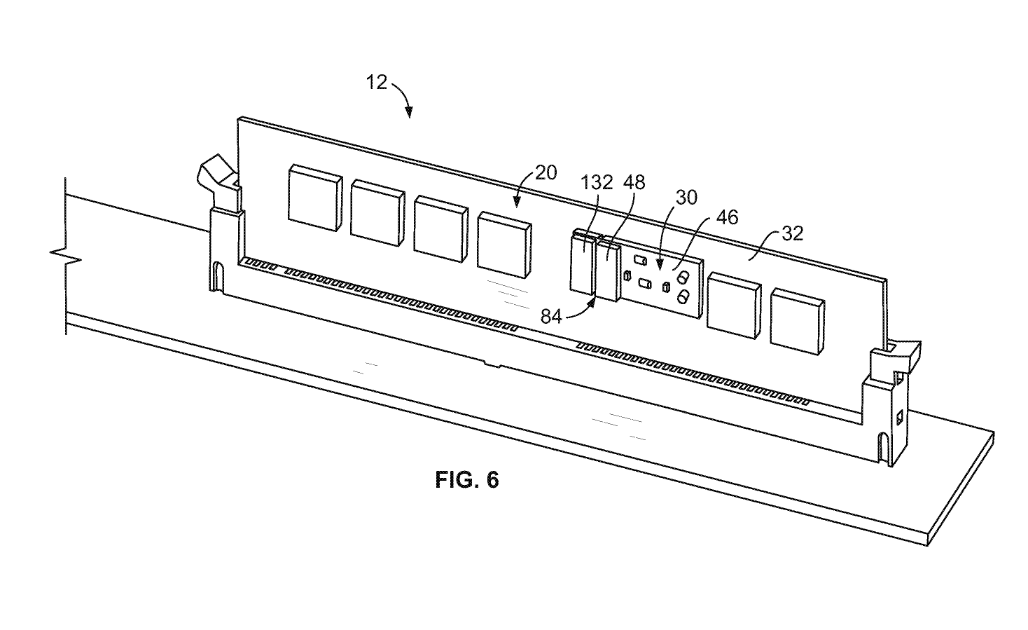

FIG. 6 is a perspective view of a portion of the memory system 12, with the voltage regulator module 30 mounted to the memory module 20 in yet another alternative manner. The embodiment illustrated in FIG. 6 utilizes similar components as the embodiment illustrated in FIGS. 2 and 3, and like components are identified in FIG. 6 with like reference numerals. The voltage regulator module 30 includes the VRM circuit board 46 with the VRM connector 48 electrically connected to the VRM circuit board 46. A memory module connector 132 is electrically connected to the circuit board 32 at the VRM interface 84. In the embodiment illustrated in FIG. 6, the VRM interface 84 is located remote from the edges of the circuit board 32. For example, the VRM interface 84 is substantially centrally located on the circuit board 32. The VRM interface 84 is positioned remote from the socket interface 80.

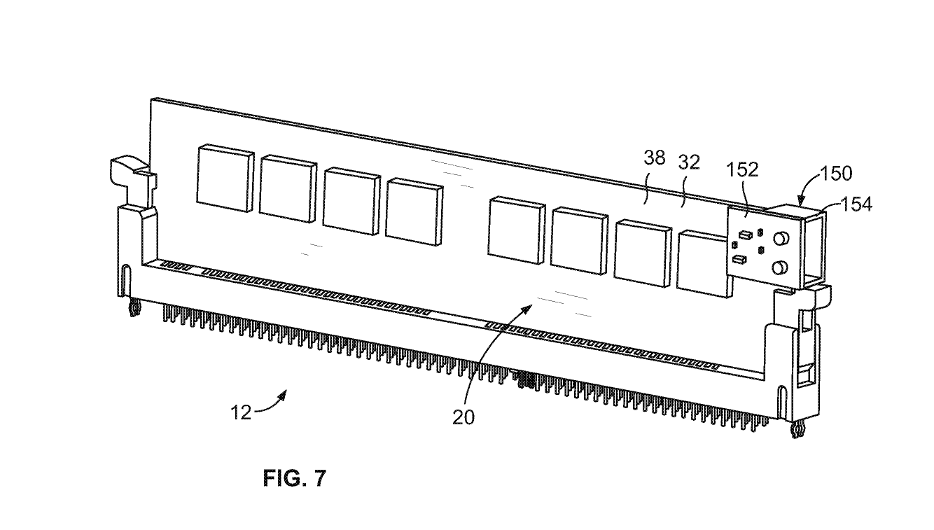

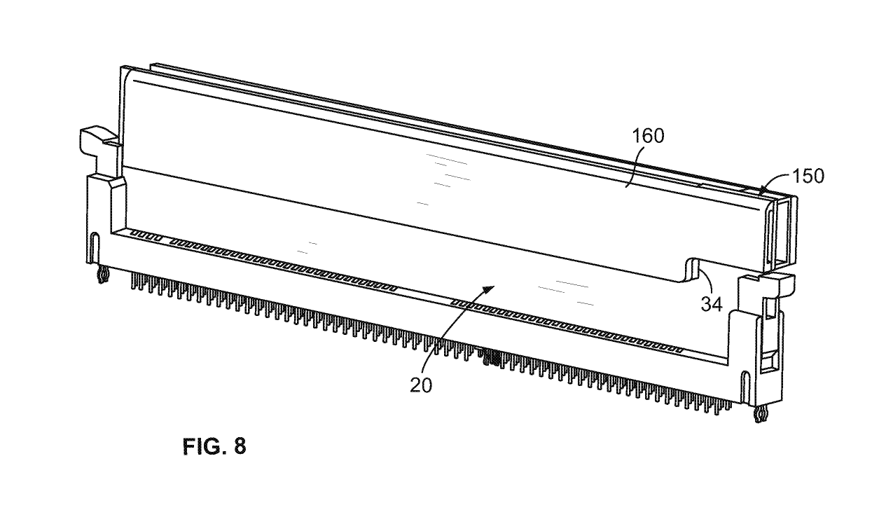

FIG. 7 is a perspective view of a portion of the memory system 12, with a voltage regulator module 150 mounted to the memory module 20 in another alternative manner. The voltage regulator module 150 is similar to the voltage regulator module 30 (shown in FIG. 2), and includes a VRM circuit board 152 and a VRM connector 154. The VRM connector 154 is surface mounted to the VRM circuit board 152. The VRM connector 154 is coupled to the memory module 20. In the illustrated embodiment, the VRM circuit board 152 extends along the second side 38 of the circuit board 32 of the memory module 20 when the VRM connector 154 is coupled to the circuit board 32.

FIG. 8 illustrates heat sinks 160 coupled to the memory module 20 and voltage regulator module 150. One or the heat sinks 160 is in thermal contact with the voltage regulator module 150, and more particularly with the heat generating components of the voltage regulator module 150. The heat sinks 160 are also in thermal contact with the memory devices 34 of the memory module 20. Optionally, different heat sinks 160 may be used for the memory devices 34 and/or the voltage regulator module 30. Any number of heat sinks 160 may be provided depending on the particular application. The heat sinks 160 may be coupled to the memory module 20, the memory devices 34, the voltage regulator module 150 and/or other structures in any known manner such that the heat sinks 160 are in thermal engagement with the desired components. Optionally, the heat sinks 160 may provide structural support for the voltage regulator module 150 and/or the memory devices 34.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means—plus-function format and are not intended to be interpreted based on 35 U.S.C. §112, sixth paragraph, unless and until such claim limitations expressly use the phrase “means for” followed by a statement of function void of further structure.

What is claimed is:

1. A memory module comprising:
a circuit board having socket mating contacts at a socket interface and voltage regulator module (VRM) contacts at a VRM interface;
memory devices coupled to the circuit board, the memory devices being electrically connected to corresponding socket mating contacts and the memory devices being electrically connected to corresponding VRM contacts; and
a voltage regulator module coupled to the circuit board at the VRM interface, the voltage regulator module having mating contacts directly connected to the VRM contacts.

2. The memory module of claim 1, wherein the voltage regulator module is supported by the circuit board.

3. The memory module of claim 1, wherein the voltage regulator module is coupled to the VRM interface remote from the socket interface.

4. The memory module of claim 1, wherein the circuit board is configured to be coupled to a system board at the socket interface, the circuit board being oriented at a right angle with respect to the system board.

5. The memory module of claim 1, wherein the socket interface is provided at an edge of the circuit board, the VRM interface is provided at a different edge of the circuit board.

6. The memory module of claim 1, wherein the circuit board includes a finger at an edge thereof, the VRM contacts extend along the finger, the voltage regulator module includes a card edge connector that receives the finger of the circuit board to engage the VRM contacts.

7. The memory module of claim 1, further comprising a VRM connector mounted to the circuit board, the voltage regulator module being connected to the VRM connector.

8. The memory module of claim 1, wherein the voltage regulator module includes a VRM circuit board, the VRM circuit board being substantially coplanar with the circuit board of the memory module.

9. The memory module of claim 1, wherein the voltage regulator module includes a VRM circuit board, the VRM circuit board being substantially parallel to, and non-coplanar with, the circuit board.

10. The memory module of claim 1, wherein the voltage regulator module includes an input and an output both coupled to the VRM contacts.

11. The memory module of claim 1, further comprising one or more heat sinks operatively coupled to at least one of the voltage regulator module and the memory devices.

12. The memory module of claim 1, wherein the VRM contacts are electrically connected to corresponding socket mating contacts via the circuit board and the memory devices are electrically connected to corresponding VRM contacts via the circuit board.

13. The memory module of claim 1, further comprising a socket connector having an opening, the socket connector receives the circuit board such that the socket interface is received in the opening, the voltage regulator module being coupled to the circuit board remote from the socket connector.

14. A voltage regulator module for a memory module, the voltage regulator module comprising:
a circuit board having a power circuit for regulating power; and
a VRM connector coupled to the circuit board, the VRM connector configured to mate with the memory module, the VRM connector having power-in contacts and power-out contacts coupled to the power circuit, wherein the power-in contacts are configured to receive a power supply from the memory module, and wherein the power-out contacts are configured to supply power to the memory module.

15. The voltage regulator module of claim 14, wherein the VRM connector defines a card edge connector configured to receive an edge of a circuit board of the memory module.

16. The voltage regulator module of claim 14, wherein the power circuit is configured to regulate the power supply to memory devices on the memory module.

17. The voltage regulator module of claim 14, wherein the power-in contacts are configured to receive power from a system board via the memory module.

18. The voltage regulator module of claim 14, wherein the VRM connector is configured to mate with a circuit board of the memory module such that the circuit board of the voltage regulator module is oriented parallel to the circuit board of the memory module.

19. A memory system for an electronic device having a power source of electrically connected thereto, the memory system comprising:
a system board having a socket connector, the system board relaying power from the power source to the socket connector; and
a memory module coupled to the socket connector, the memory module comprising:
a circuit board having socket mating contacts at a socket interface and VRM contacts at a VRM interface, at least some of the socket mating contacts being electrically connected to the power source via the socket connector, and at least some of the VRM contacts being electrically connected to corresponding socket mating contacts via the circuit board;
memory devices coupled to the circuit board, the memory devices being electrically connected to corresponding socket mating contacts and the memory devices being electrically connected to corresponding VRM contacts; and
a voltage regulator module coupled to the circuit board at the VRM interface, the voltage regulator module being electrically connected to the VRM contacts.

20. The memory system of claim 19, wherein the voltage regulator module is coupled to the circuit board remote from the socket connector.
